(19) United States
(12) Patent Application Publication
(10) Pub. No.: US 2025/0280637 A1
(43) Pub. Date: Sep. 4, 2025

(54) DISPLAY PANEL AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yanwei Lu, Beijing (CN); Zhenli Zhou, Beijing (CN); Zhuoran Yan, Beijing (CN); Hongjun Zhou, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/702,537

(22) PCT Filed: Aug. 11, 2023
(86) PCT No.: PCT/CN2023/112536

§ 371 Date: Apr. 18, 2024

(30) Foreign Application Priority Data
Sep. 29, 2022 (CN) 202211204118.7

(51) Int. Cl. H10H 29/30; H10H 29/49

(52) U.S. Cl. CPC H10H 29/352; H10H 29/49

(57) ABSTRACT

A display panel and a display device are provided. The display panel includes: a display region and a non-display region, the non-display region surrounds the display region, the display region includes a first display region and a second display region, the first display region surrounds the periphery of the second display region, a plurality of first pixels is arranged in the first display region, a plurality of second pixels is arranged in the second display region, the display region includes a first driving circuit configured to drive the first pixels and a second driving circuit configured to drive the second pixels; and one first driving circuit is configured to simultaneously drive at least two first pixels.

### CROSS-REFERENCE TO RELATED APPLICATIONS

The present application claims priority to Chinese Patent Application No. 202211204118.7 filed in China on Sep. 29, 2022, which is incorporated herein by reference in its entirety.

### TECHNICAL FIELD

The present disclosure relates to the field of display technologies, in particular to a display panel and a display device.

### BACKGROUND

Nowadays, there are more and more electronic products, such as mobile phones, televisions, tablets and wearable products. With the development of electronic products, a display technology has been widely used. The functions and usage scenarios of display products are becoming more numerous, leading to higher demands on the display area of display devices. In a display device, the wider a border of the device is, the larger a non-display region is, and the smaller an area of an actual display region is. For some miniaturized display panels, such as various types of special-shaped wearable products, for example, a circular-shaped display device with rounded corners, the border of the non-display region is relatively wide due to the presence of rounded corners, so that an area of the display region is small and a screen-to-body ratio is low, and it is difficult to meet the requirements on the narrow border of the display product, thereby adversely affecting the user's experience.

### SUMMARY

An object of embodiments of the present disclosure is to provide a display panel and a display device.

In a first aspect, the embodiments of the present disclosure provide a display panel, including a display region and a non-display region. The non-display region surrounds the display region, the display region includes a first display region and a second display region, the first display region surrounds the periphery of the second display region, a plurality of first pixels is arranged in the first display region, a plurality of second pixels is arranged in the second display region, the display region includes a first driving circuit configured to drive the first pixels and a second driving circuit configured to drive the second pixels, and one first driving circuit is configured to simultaneously drive at least two first pixels.

Optionally, one first driving circuit is configured to simultaneously drive two first pixels in two adjacent columns respectively.

Optionally, two first pixels respectively in two columns driven simultaneously by a same first driving circuit are in a same row.

Optionally, at least part of the first driving circuit is arranged in the second display region.

Optionally, the display panel further includes: connection lines, each of the connection lines is connected to electrodes of at least two first pixels, and each first driving circuit is electrically connected to a corresponding one of the connection lines.

Optionally, each of the connection lines is connected to two adjacent first pixels.

Optionally, each of the first pixels includes a first sub-pixel, and one first driving circuit is configured to simultaneously drive first sub-pixels of at least two first pixels.

Optionally, each of the first pixels includes a second sub-pixel, and one first driving circuit is configured to simultaneously drive second sub-pixels of at least two first pixels, where the first sub-pixel and the second sub-pixel emit light in different colors.

Optionally, the first pixel includes: a first electrode, a light-emitting unit and a second electrode laminated one on another, and one first driving circuit is configured to connect electrodes in at least two first pixels.

Optionally, the display panel further includes: a detection circuit configured to detect brightness of a pixel, at least part of the detection circuit being located in the first display region.

Optionally, the display panel further includes: a branching unit, and the first driving circuit is electrically connected to the first pixels via the branching unit.

Optionally, at least part of the branching unit is located in the first display region.

Optionally, the first display region includes a first region, a second region, a third region and a fourth region, the first region, the second region, the third region and the fourth region are distributed along the periphery of the second display region, and the first pixels are arranged in at least one of the first region, the second region, the third region and the fourth region.

Optionally, a distribution density of the first pixels in the first display region is less than a distribution density of the second pixels in the second display region.

In a second aspect, the embodiments of the present disclosure provide a display device including the display panel described in the above embodiments; and the display device further includes: a frame body covering the non-display region.

### BRIEF DESCRIPTION OF THE DRAWINGS

FIG. 1a is a schematic view showing a distribution of a display region and a non-display region according to the embodiments of the present disclosure;

FIG. 1b is another schematic view showing the distribution of the display region and the non-display region in an embodiment of the present disclosure;

FIG. 1c is yet another schematic view showing the distribution of the display region and the non-display region according to the embodiments of the present disclosure;

FIG. 1d is still yet another schematic view showing the distribution of the display region and the non-display region according to the embodiments of the present disclosure;

FIG. 1e is still yet another schematic view showing the distribution of the display region and the non-display region according to the embodiments of the present disclosure;

FIG. 1f is still yet another schematic view showing the distribution of the display region and the non-display region according to the embodiments of the present disclosure;

FIG. 1g is still yet another schematic view showing the distribution of the display region and the non-display region according to the embodiments of the present disclosure;

FIG. 2 is a schematic view showing a connection between a connection line and a pixel region according to the embodiments of the present disclosure;

FIG. 3 is a schematic view showing a connection between a connection line and electrodes according to the embodiments of the present disclosure;

FIG. 4 is another schematic view showing the connection between the connection line and the pixel region according to the embodiments of the present disclosure;

FIG. 5 is another schematic view showing the connection between the connection line and the electrodes according to the embodiments of the present disclosure;

FIG. 6 is a schematic view showing a case where a connection line is connected to electrodes and a first driving circuit according to the embodiments of the present disclosure;

FIG. 7 is another schematic view showing the connection between the connection line and the pixel region according to the embodiments of the present disclosure;

FIG. 8 is a schematic view showing a connection between a connection line and a pixel according to the embodiments of the present disclosure;

FIG. 9 is another schematic view showing the connection between the connection line and the pixel according to the embodiments of the present disclosure;

FIG. 10 is yet another schematic view showing the connection between the connection line and the pixel according to the embodiments of the present disclosure; and

FIG. 11 is still yet another schematic view showing the connection between the connection line to the pixel according to the embodiments of the present disclosure.

### REFERENCE SIGN LIST

10 display region
11 first display region
12 second display region
111 first region
112 second region
113 third region
114 fourth region
20 non-display region
21 border region
30 first pixel
31 first sub-pixel
32 second sub-pixel
33 third sub-pixel
40 second pixel
51 first driving circuit
52 second driving circuit
60 connection line
61 branching unit
62 pixel region

### DETAILED DESCRIPTION

The technical solutions in the embodiments of the present disclosure will be described hereinafter clearly and completely with reference to the drawings of the embodiments of the present disclosure. Apparently, the following embodiments merely relate to a part of, rather than all of, the embodiments of the present disclosure, and based on these embodiments, a person of ordinary skill in the art may, without any creative effort, obtain other embodiments, which also fall within the scope of the present disclosure.

Terms such as “first” and “second” in the description and the claims of the present disclosure are used to distinguish similar objects and are not necessarily used to describe a specific order or sequence. It should be understood that the terms used in this way may be interchanged under appropriate circumstances, so that the embodiments of the present disclosure described herein may be implemented in a sequence other than those illustrated or described herein. In addition, in the description and the claims, “and/or” means at least one of the connected objects, and the character “/” generally means that the associated objects are in an “or” relationship.

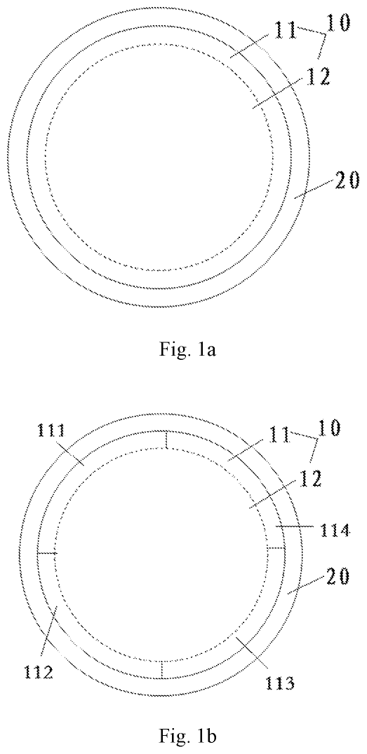

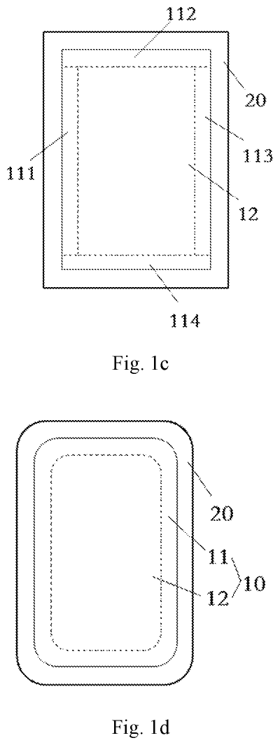

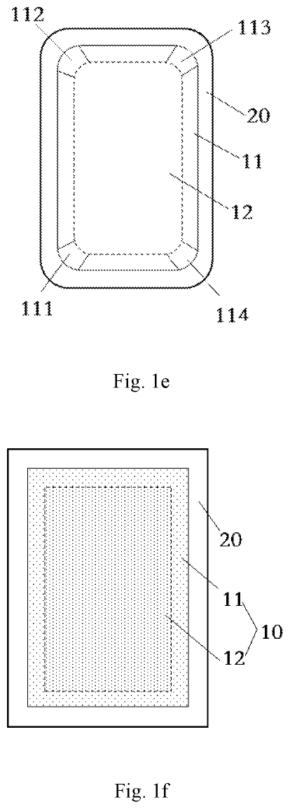

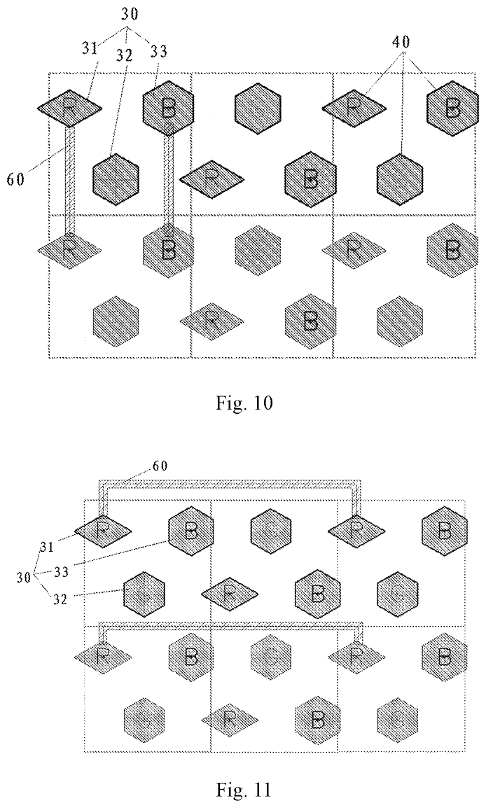

Hereinafter, a display panel according to the embodiments of the present disclosure will be described in detail with reference to FIGS. 1a to 11 through specific embodiments and application scenarios thereof.

As shown in FIGS. 1a to 11, the display panel of the embodiments of the present disclosure includes: a display region 10 and a non-display region 20 surrounding the display region 10, and the display panel may have a circular shape or a rectangular shape. The display panel may be a non-flexible panel, and may be applied to a mobile phone, a tablet, a computer, and a wearable device such as a watch. The display region 10 includes a first display region 11 and a second display region 12, the first display region 11 surrounds the periphery of the second display region 12, a plurality of first pixels 30 is arranged in the first display region 11, a plurality of second pixels 40 is arranged in the second display region 12, light-emission colors of the first pixels 30 and the second pixels 40 may be the same or different, and a distribution density or arrangement manner of the first pixels 30 may be the same with, or different from, a distribution density or arrangement manner of the second pixels 40. The display region 10 includes a first driving circuit 51 configured to drive the first pixels 30 and a second driving circuit 52 configured to drive the second pixels 40, one first driving circuit 51 is configured to drive at least two first pixels 30 simultaneously. The first display region 11 may have a pixel region 62, each first pixel 30 may be arranged in the corresponding pixel region 62, and the first driving circuit 51 may be connected to the first pixel 30 through a via hole of the pixel region 62. One second driving circuit 52 may drive one or more second pixels 40, for example, each second driving circuit 52 may drive one second pixel 40. At least two first pixels 30 may be driven simultaneously by one first driving circuit 51, for example, two first pixels 30 may be driven simultaneously by one first driving circuit 51. When one first driving circuit 51 simultaneously drives two first pixels 30, it is able to reduce the quantity of first driving circuits 51, thereby to reduce the space occupied by the first driving circuits 51. The saved space may be used to accommodate other lines or devices, which is beneficial to increasing an area of the display region, and narrowing a border of the display panel.

As shown in FIGS. 1a to 1g, the display region 10 includes a first display region 11 and a second display region 12, the first display region 11 surrounds the periphery of the second display region 12, the first display region 11 may extend along the periphery of the second display region 12, and the display region 10 may be a circular-shaped display region, an elliptical-shaped display region, a polygonal-shaped display region or a display region with rounded corners. The second display region 12 may be a circular-shaped display region, an elliptical-shaped display region, a polygonal-shaped display region or a display region with rounded corners. The first display region 11 may be ring-shaped, frame-shaped, arc-shaped or long strip-shaped. Specific shapes of the first display region 11 and the second display region 12 may be determined according to actual needs, and shapes and sizes of the first display region 11 and the second display region 12 may be matched according to practical applications.

For example, in the display panel, as shown in FIGS. 1a to 1b, the display region 10 of the display panel may be circular-shaped, the second display region 12 may be circular-shaped, the first display region 11 may be ring-shaped, and the first display region 11 is located at a peripheral region of the display region. For example, in the display panel, the display region 10 of the display panel may have an elliptical shape, the second display region 12 may have an elliptical shape, the first display region 11 may have a ring shape, and the first display region 11 is located at a peripheral region of the display region. For example, in the display panel, the display region 10 of the display panel may have an elliptical shape, the second display region 12 may have an elliptical shape, the first display region 11 may have a ring shape, and the first display region 11 is located at a peripheral region of the display region. For example, in the display panel, the display region 10 of the display panel may have a rectangular shape, the second display region 12 may have a rectangular shape, the first display region 11 may have a frame shape, and the first display region 11 is located at a peripheral region of the display region.

In some embodiments, as shown in FIGS. 1c and 1f, the display region 10 of the display panel may be rectangular-shaped, the second display region 12 may be rectangular-shaped, the first display region 11 may be frame-shaped, and the first display region 11 is located at the peripheral region of the display region.

The first display region 11 may include a first region 111, a second region 112, a third region 113 and a fourth region 114, as shown in FIGS. 1b and 1c, the first region 111, the second region 112, the third region 113 and the fourth region 114 may be successively distributed along the periphery of the second display region 12. The first region 111, the second region 112, the third region 113 and the fourth region 114 may be sequentially in contact with and connected to encircle and form the first display region 11, adjacent ones of the first region 111 and the second region 112, the third and fourth regions 113, 114 may be spaced apart from each other without contact, the first and third regions 111, 113 may be arranged opposite to each other, and the second and fourth regions 112, 114 may be arranged opposite to each other.

For example, as shown in FIG. 1b, in the case where the first display region 11 has a ring shape, the first region 111, the second region 112, the third region 113 and the fourth region 114 may each have an arc shape, the first region 111, the second region 112, the third region 113, the fourth region may be concentrically distributed as the second display region 12, and the first display region 11 may be formed by the first region 111, the second region 112, the third region 113 and the fourth region that are sequentially in contact with and connected to.

As shown in FIG. 1c, in the case where the first display region 11 is of a frame shape, the first region 111, the second region 112, the third region 113 and the fourth region 114 may each be of a strip-like shape, or the first region 111, the second region 112, the third region 113 and the fourth region 114 may each be of a rectangular shape, the first region 111 and the third region 113 may be arranged in parallel and spaced apart from each other, the second region 112 and the fourth region 114 may be distributed in parallel and spaced apart from each other, the first region 111 and the second region 112 may be distributed vertically, and the third region 113 and the fourth region 114 may be distributed vertically.

In the display panel, as shown in FIG. 1d, the display region 10 of the display panel may be a display region having rounded corners, the display region 10 of the display panel may be a display region having one or more rounded corners, for example, the display region 10 may be substantially quadrangular-shaped, the display region 10 may have four rounded corners, the first display region 11 may be located at a peripheral region of the display region, the rounded corners may be located at corners of the display region, and the rounded corners may be located in the first display region 11. As shown in FIG. 1e, adjacent ones of the first region 111, the second region 112, the third region 113 and the fourth region 114 may be spaced apart from each other, the first region 111 and the third region 113 may each be located at a corner of the display region, the second region and the fourth region 114 may each be located at another corner of the display region, the first region 111 and the third region 113 may be arranged opposite to each other, the second region 112 and the fourth region 114 may be arranged opposite to each other, and the first region 111, the second region 112, the third region 113 and the fourth region 114 may each be in an arc shape, so as to enable the corners of the display panel to each be of a rounded corner shape. For example, the first region 111 may be located in a lower left corner region of the display region, the second region 112 may be located in an upper left corner region of the display region, the third region 113 may be located in an upper right corner region of the display region, and the fourth region 114 may be located in a lower right corner region of the display region.

At least one of the first region 111, the second region 112, the third region 113 and the fourth region 114 may have the first pixels 30, for example, as shown in FIG. 1c, the first region 111 may be located at a left peripheral region of the display region, each first pixel 30 located in the first region 111 may be arranged in a corresponding pixel region 62, and the first driving circuit 51 may be connected to the first pixel 30 in the first region 111 through a via hole of the pixel region 62. At least two first pixels 30 located in the first region 111 may be driven simultaneously by one first driving circuit 51, for example, two first pixels 30 located in the first region may be driven simultaneously by one first driving circuit 51. When one first driving circuit 51 simultaneously drives two first pixels 30 located in the first region 111, it is able to reduce the quantity of first driving circuits 51 required for the first pixels 30 located in the first region 111, thereby to reduce the space occupied by the first driving circuits 51. The saved space may be used to accommodate other lines or devices, which is beneficial to narrowing the border of the display panel close to the first region 111.

As shown in FIG. 1c, the second region 112 may be located at an upper peripheral region of the display region, each first pixel 30 located at the second region 112 may be arranged in a corresponding pixel region 62, and the first driving circuit 51 may be connected to the first pixel 30 in the second region 112 through a via hole of the pixel region 62. At least two first pixels 30 located in the second region 112 may be driven simultaneously by one first driving circuit 51, for example, two first pixels 30 located in the second region 112 may be driven simultaneously by one first driving circuit 51. When one first driving circuit 51 simultaneously drives two first pixels 30 located in the second region 112, it is able to reduce the quantity of first driving circuits 51 required for the first pixels 30 located in the second region 112, thereby to reduce the space occupied by the first driving circuits 51. The saved space may be used to accommodate other lines or devices, which is beneficial to narrowing the border of the display panel close to the second region 112.

As shown in FIG. 1c, the third region 113 may be located at a right peripheral region of the display region, each first pixel 30 located at the third region 113 may be arranged in a corresponding pixel region 62, and the first driving circuit 51 may be connected to the first pixel 30 in the third region 113 through a via hole of the pixel region 62. At least two first pixels 30 located in the third region 113 may be driven simultaneously by one first driving circuit 51, for example, two first pixels 30 located in the third region 113 may be driven simultaneously by one first driving circuit 51. When one first driving circuit 51 simultaneously drives two first pixels 30 located in the third region 113, it is able to reduce the quantity of first driving circuits 51 required for the first pixels 30 located in the third region 113, thereby to reduce the space occupied by the first driving circuit 51. The saved space may be used to accommodate other lines or devices, which is beneficial to narrowing the border of the display panel close to the third region 113.

As shown in FIG. 1c, the fourth region 114 may be located at a lower peripheral region of the display region, each first pixel 30 located at the fourth region 114 may be arranged in a corresponding pixel region 62, and the first driving circuit 51 may be connected to the first pixel 30 in the fourth region 114 through a via hole of the pixel region 62. At least two first pixels 30 located in the fourth region 114 may be driven simultaneously by one first driving circuit 51, for example, two first pixels 30 located in the fourth region 114 may be driven simultaneously by one first driving circuit 51. When one first driving circuit 51 simultaneously drives two first pixels 30 located in the fourth region 114, it is able to reduce the quantity of first driving circuits 51 required for the first pixels 30 located in the fourth region 114, thereby to reduce the space occupied by the first driving circuit 51. The saved space may be used to accommodate other lines or devices, which is beneficial to narrowing the border of the display panel close to the fourth region 114.

The display panel may have a circular shape, an elliptical shape, a polygonal shape, a shape structure with rounded corners, etc. and the display region of the display panel may have a circular shape, an elliptical shape, a polygonal shape, a shape structure with rounded corners, etc. and the display region may match the display panel in shape. In the application process, according to practical needs, at least two first pixels 30 among the first pixels 30 of at least one of the first region 111, the second region 112, the third region 113 and the fourth region 114 may be driven simultaneously by one first driving circuit 51, for example, two first pixels 30 may be driven simultaneously by one first driving circuit 51. Thus, the quantity of first driving circuits 51 required for the first pixels 30 in at least one of the first region 111, the second region 112, the third region 113 and the fourth region 114 may be reduced, the space occupied by the first driving circuits 51 is also reduced, and the saved space may be used to accommodate other lines or devices, which is advantageous for narrowing the border of the corresponding region of the display panel.

As shown in FIG. 1f, the display region 10 may include a first display region 11 and a second display region 12. The first display region 11 surrounds the periphery of the second display region 12, a plurality of first pixels 30 is arranged in the first display region 11, a plurality of second pixels 40 is arranged in the second display region 12, and a distribution density of the first pixels 30 may be the same with, or different from, a distribution density of the second pixels 40. The first pixels 30 may be evenly distributed and spaced apart from each other, and the second pixels 40 may be evenly distributed and spaced apart from each other. The distribution density of the first pixels 30 in the first display region 11 may be less than the distribution density of the second pixels 40 in the second display region 12. Since the distribution density of the first pixels 30 in the first display region 11 is less than the distribution density of the second pixels 40 in the second display region 12, the quantity of first driving circuits required for driving the first pixels 30 in the first display region 11 is reduced, the space occupied by the first driving circuits 51 is reduced, and the saved space may be used to accommodate other lines or devices, which is beneficial to increasing the area of the display region and narrowing the border of the display panel.

As shown in FIG. 1g, the distribution density of the first pixels 30 in at least one of the first region 111, the second region 112, the third region 113 and the fourth region 114 is less than the distribution density of the second pixels 40 in the second display region 12. For example, the distribution density of the first pixels 30 in the first region 111 is less than the distribution density of the second pixels 40 in the second display region 12. Since the distribution density of the first pixels 30 in the first region 111 is less than the distribution density of the second pixels 40 in the second display region 12, the quantity of the first driving circuits required for driving the first pixels 30 in the first region 111 is reduced, the space occupied by the first driving circuits 51 is reduced, and the saved space may be used to accommodate other lines or devices, which is advantageous for increasing the area of the display region and for narrowing the border of the display panel narrower.

As shown in FIG. 1g, in each of the first region 111, the second region 112, the third region 113 and the fourth region 114, the distribution density of the first pixels 30 is less than the distribution density of the second pixels 40 in the second display region 12, the brightness of the first pixels 30 is greater than the brightness of the second pixels 40 in the second display region 12, so as to reduce a brightness difference caused by the distribution density of the first pixels 30 being less than the distribution density of the second pixels 40 in the second display region 12. Therefore, the brightness difference between the first pixels 30 and the second pixels 40 with different distribution densities is not easily observed, thereby improving the display effect and improving the viewing experience of a user.

The second display region 12 may include a peripheral region and a central region, the peripheral region may surround the periphery of the central region, the peripheral region is located between the first display region 11 and the central region, and distribution densities of the second pixels 40 in the peripheral region and the central region may be the same or different. For example, the distribution densities of the second pixels 40 in the peripheral region and the central region may be different, the distribution density of the second pixels 40 in the peripheral region may be less than the distribution density of the second pixels 40 in the central region, and the distribution density of the first pixels 30 in at least one of the first region 111, the second region 112, the third region 113 and the fourth region 114 is less than the distribution density of the second pixels 40 in the peripheral region. For example, the distribution density of the first pixels 30 in the first region 111 is less than the distribution density of the second pixels 40 in the peripheral region. The peripheral region may serve as a transition region, and the brightness difference caused by the distribution density of the first pixels 30 in the first display region 11 being less than the distribution density of the second pixels 40 in the second display region 12 may not easily observed through the second pixels 40 in the peripheral region, thereby improving the display effect and improving the viewing experience of the user.

The central region may be a circular-shaped display region, an elliptical-shaped display region, a polygonal-shaped display region, and a display region with rounded corners. The peripheral region may be ring-shaped, frame-shaped, arc-shaped or strip-shaped. Specific shapes of the peripheral region and the central region may be determined according to actual needs, and shapes and sizes of the peripheral region and the central region may be matched according to practical applications.

One first driving circuit 51 may drive at least two first pixels 30 simultaneously, one second driving circuit 52 may drive one or more second pixels 40, e.g., one first driving circuit 51 may drive two first pixels 30 simultaneously, each second driving circuit 52 may drive one second pixel 40. At least two first pixels 30 may be driven simultaneously by one first driving circuit 51, at least part of the first driving circuit 51 may be located in the second display region 12, and at least part of the first driving circuit 51 may be located in the peripheral region or the central region of the second display region 12, so as to reduce the space occupied by the first driving circuit 51 in the first display region 11. Hence, the saved space may be used to accommodate other lines or devices, which is beneficial to increasing the area of the display region and narrowing the border of the display panel.

In the display panel of the embodiments of the present disclosure, the display region 10 includes the first driving circuit 51 configured to drive the first pixel 30 and the second driving circuit 52 configured to drive the second pixel 40, one first driving circuit 51 is used to drive at least two first pixels 30 simultaneously. In the first display region 11, one first driving circuit 51 is used to simultaneously drive at least two first pixels 30, so it is able to reduce the quantity of the first driving circuits, thereby to reduce the space occupied by the first driving circuits. Hence, a part of the space may be saved in the peripheral region, and some other traces may be arranged in the saved space, so that the border of the display panel may be narrower, thereby to increase the area of the display region, improve the screen-to-body ratio, meet the requirement on the narrow border of the display product, and improve the user experience.

In some embodiments, when one first driving circuit 51 is used to drive two first pixels 30 in two columns simultaneously, it may reduce the difference in gray scale, thereby to avoid the occurrence of serrated display in the periphery and provide more uniform display. One first driving circuit 51 is configured to simultaneously drive two first pixels 30 in two columns respectively, and the two first pixels 30 in the two columns respectively may be in two adjacent columns respectively, such as a first column and a second column. The two first pixels 30 in the two columns respectively may be in two non-adjacent columns respectively, for example, the two first pixels 30 in the two columns respectively may be in the first column and the third column, or the two first pixels 30 in the two columns respectively may be in the first column and the fourth column. One first driving circuit 51 drives the two first pixels 30 in the two columns simultaneously, so as to facilitate the connection, which is beneficial to reducing the length of each of the lines through which the first driving circuit 51 is connected to the two first pixels 30. The first pixels 30 may be arranged in an array form, one first driving circuit 51 may simultaneously drive two first pixels 30 in two columns respectively. The two first pixels 30 in two columns respectively driven simultaneously by the same first driving circuit 51 may be located in a same row, so as to provide a relatively small length difference between the lines through which the first driving circuit 51 is connected to two first pixels 30, thereby to further reduce the length of each of the lines through which the first driving circuit 51 is connected to two first pixels 30. One first driving circuit 51 is configured to simultaneously drive two first pixels 30 in two adjacent columns respectively, and the first pixels 30 may be arranged in an array form. When one first driving circuit 51 simultaneously drives two first pixels 30 in two columns respectively, two first pixels 30 in two columns respectively which are driven at the same time by the same first driving circuit 51 may be located in the same row, it is able to provide a relatively small length difference between the lines through which the first driving circuit 51 is connected to two first pixels 30, thereby to further reduce the length of each of the lines through which the first driving circuit 51 is connected to two first pixels 30, and facilitating the connection between the first driving circuit 51 and the first pixels 30. In addition, it is also able to reduce the space occupied by the lines through which the first driving circuit 51 is connected to two first pixels 30, and the saved space may be used to accommodate other lines or devices, which is beneficial to narrowing the border of the display panel.

In other embodiments, at least a portion of the first driving circuit 51 is disposed in the second display region 12, for example, a portion of the first driving circuit 51 may be disposed in the second display region 12. The first driving circuit 51 may be arranged entirely in the second display region 12, so that the first display region 11 has an anode and an opening for the pixel to emit light, without the first driving circuit 51. Providing at least part of the first driving circuit 51 in the second display region 12 is advantageous for saving the space occupied by the first driving circuit 51 in the first display region 11 and for making the border narrower. For example, one first driving circuit 51 may drive at least two first pixels 30 at the same time, one second driving circuit 52 may drive one or more second pixels 40, at least two first pixels 30 may be driven at the same time via one first driving circuit 51, at least part of the first driving circuit 51 may be located in the peripheral region or the central region of the second display region 12, the space occupied by the first driving circuit 51 in the first display region 11 is reduced, and the saved space may be used to accommodate other lines or devices, which is beneficial to increasing the area of the display region and for making the border of the display panel narrower.

Optionally, the display panel further includes: connection lines 60, each connection line 60 is connected to the electrodes of at least two first pixels 30, and each first driving circuit 51 is electrically connected to a corresponding connection line 60. The connection line 60 may be a metal line, and the material of the metal line may include at least one of aluminum, copper, molybdenum, titanium or silver. For example, the material of the metal line may include molybdenum or silver, allowing the metal line to have a higher conductivity and reducing losses. The connection line 60 may be a separate line, and the connection line 60 may be arranged at a same layer as a gate electrode, or may be located above or below the gate electrode layer, which may be determined according to practical needs. The connection line 60 may be arranged above or below an anode layer; the material of the connection line 60 may be the same with or different from the material of the anode layer. For example, the material of the connection line 60 may be the same as the material of the anode layer, with both the material of the connection line 60 and the material of the anode layer being indium tin oxide (ITO), which has a better light transmittance. Using the same material facilitates processing and manufacturing, simplifying the process. The connection line 60 may serve as the anode layer, and there is no need to separately form the connection line 60, further simplifying the process. The anode layer serve as a light transmitting material layer, for example, the anode layer may be an indium tin oxide (ITO) layer, which may improve light transmittance and reduce power consumption. For example, each connection line 60 is connected to the electrodes of two first pixels 30, and each first driving circuit 51 is electrically connected to a corresponding connection line 60. Each connection line 60 is connected to the electrodes of two first pixels 30 in two adjacent columns respectively, and two first pixels 30 in two adjacent columns respectively connected to the same connection line 60 may be located in the same row, which is beneficial to reducing the length of the connection line 60 and reducing the space occupation.

Optionally, each connection line 60 is connected to two adjacent first pixels 30, for example, the two adjacent first pixels 30 connected to each connection line 60 may be located in the same row or the same column, which is beneficial to reducing the length of the connection line 60, reducing the occupation of space, and saved space may be used to accommodate other lines or devices, which is advantageous in making the border of the display panel narrower.

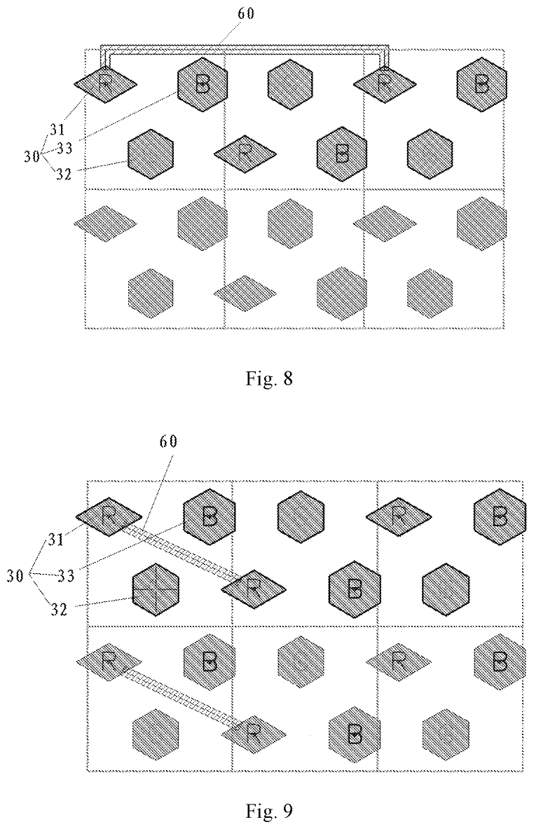

In some embodiments, as shown in FIGS. 8 to 11, each first pixel 30 includes a first sub-pixel 31, one first driving circuit 51 is configured to first sub-pixels 31 of at least two first pixels 30 simultaneously. For example, each first pixel 30 may include one or more first sub-pixels 31, the first sub-pixel 31 may be a red pixel, and one first driving circuit 51 may drive the first sub-pixels 31 of two first pixels 30 at the same time. Hence, it is able for the same first driving circuit 51 to drive the first sub-pixels 31 of two first pixels 30 at the same time, which is beneficial to saving the space occupied by the first driving circuit 51 in the first display region 11 and to facilitating a narrower border.

Optionally, as shown in FIGS. 8 to 11, each first pixel 30 includes a second sub-pixel 32, one first driving circuit 51 is configured to simultaneously drive second sub-pixels 32 of at least two first pixels 30, and the first sub-pixel 31 and the second sub-pixel 32 emit light in different colors. For example, each first pixel 30 may include one or more second sub-pixels 32, the second sub-pixels 32 may be green pixels, one first driving circuit 51 may drive the second sub-pixels 32 of the two first pixels 30 simultaneously, and the first driving circuit 51 driving the first sub-pixels 31 of the two first pixels 30 simultaneously is not the same as the first driving circuit 51 driving the second sub-pixels 32 of the two first pixels 30 simultaneously. Hence, it is able for the same first driving circuit 51 to drive the second sub-pixels 32 of the two first pixels 30 at the same time, which is advantageous to saving the space occupied by the first driving circuit 51 in the first display region 11 and facilitating a narrower border.

Optionally, as shown in FIGS. 8 to 11, each first pixel 30 includes a third sub-pixel 33, and one first driving circuit 51 is configured to simultaneously drive third sub-pixels 33 of at least two first pixels 30, the first sub-pixel 31, the second sub-pixel 32 and the third sub-pixel 33 emit light in different colors. For example, each first pixel 30 may include one or more third sub-pixels 33, the third sub-pixels 33 may be blue pixels, one first driving circuit 51 may simultaneously drive the third sub-pixels 33 of the two first pixels 30, the first driving circuit 51 simultaneously driving the first sub-pixels 31 of the two first pixels 30, and the first driving circuit 51 simultaneously driving the second sub-pixels 32 of the two first pixels 30 are not the same as the first driving circuit 51 simultaneously driving the third sub-pixels 33 of the two first pixels 30. Hence, it is able for the same first driving circuit 51 to drive the third sub-pixels 33 of the two first pixels 30 at the same time, which is advantageous to saving the space occupied by the first driving circuit 51 in the first display region 11 and facilitating a narrower border.

During the application, the first pixels 30 may be in a Delta arrangement, an S-like arrangement, a 2 in 1 arrangement, or any other arrangements such as GGRB or blue Diamond, which may be selected according to actual needs. The connection manner in which one first driving circuit 51 drives two or more first pixels 30 at the same time for different arrangements may be determined according to practical applications.

In some embodiments, the first pixel 30 includes: a first electrode, a light-emitting unit and a second electrode laminated one on another, the first electrode may be an anode and the second electrode may be a cathode, alternatively, the first electrode may be a cathode, the second electrode may be an anode. One first driving circuit 51 is configured to connect the electrodes in at least two first pixels 30, one first driving circuit 51 may apply electrical signals for the electrodes in at least two first pixels 30 at the same time, and the light-emitting unit may be driven to emit light via the first electrode and the second electrode. The first driving circuit 51 may include a first active layer, a first source electrode and a first drain electrode connected to the first active layer, and a first gate electrode, where the first source electrode and the first drain electrode may be electrically connected to the electrodes of the first pixel 30, for example, the first source electrode may be electrically connected to the first electrode, the first drain electrode may be electrically connected to the second electrode, and the first pixel 30 may be controlled to be turned on or off by the first driving circuit 51.

The second pixel 40 may include: a third electrode, a light-emitting unit and a fourth electrode laminated one on another, the third electrode may be an anode and the fourth electrode may be a cathode, alternatively, the third electrode may be a cathode, the fourth electrode may be an anode. One second driving circuit 52 may be configured to connect the electrodes in at least one second pixel 40, and the light-emitting unit may be driven to emit light via the third electrode and the fourth electrode. The second driving circuit 52 may include a second active layer, a second source electrode and a second drain electrode connected to the second active layer, and a second gate electrode, where the second source electrode and the second drain electrode may be electrically connected to the electrodes of the second pixel 40, for example, the first source electrode may be electrically connected to the third electrode, the first drain electrode may be electrically connected to the fourth electrode, and the second pixel 40 may be controlled to be turned on or off by the second driving circuit 52. The source and drain electrodes in the first driving circuit 51 and the second driving circuit 52 may be arranged in the same layer, the gate electrodes in the first driving circuit 51 and the second driving circuit 52 may be arranged in the same layer, and the active layers in the first driving circuit 51 and the second driving circuit 52 may be arranged in the same layer, thereby simplifying the process.

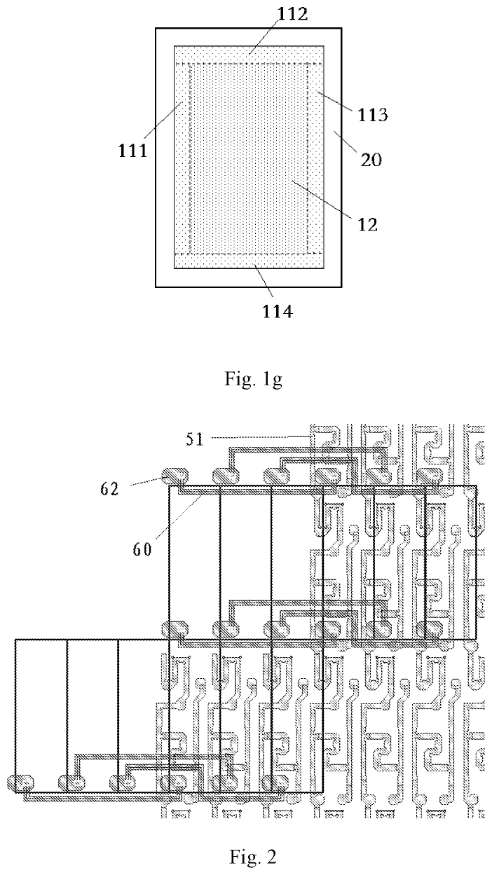

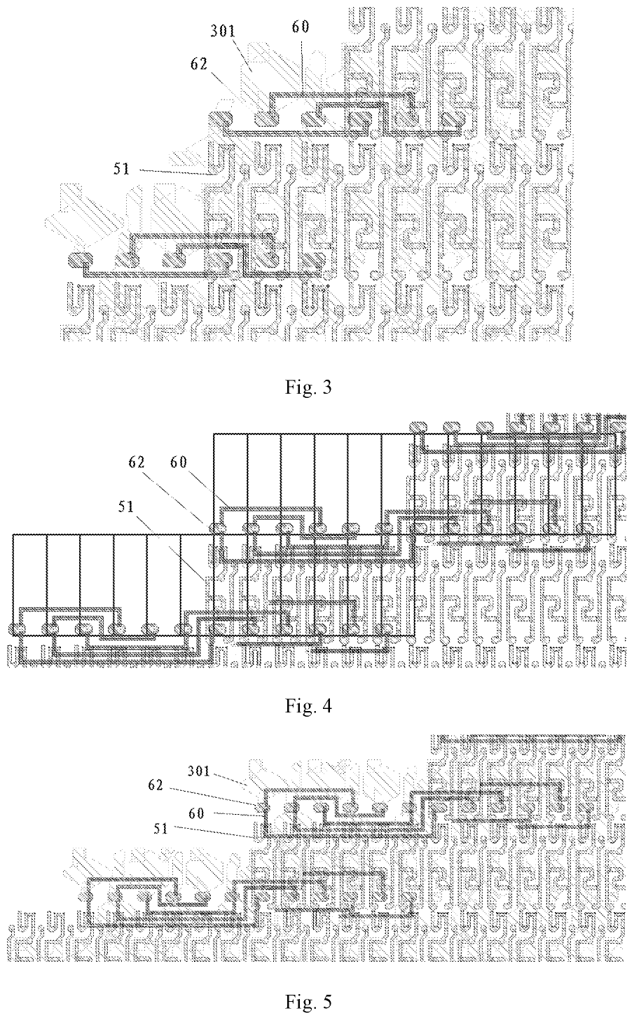

As shown in FIGS. 2 and 3, each connection line 60 is connected to two adjacent first pixels 30, and each connection line 60 is connected to the two adjacent first pixels 30 through via holes of the pixel regions 62. For example, as shown in FIG. 3, with regard to a pixel region 62 of a first row located at the top or a middle row located at the middle, a first column is located at the far left side, and one connection line 60 is connected to first sub-pixels 31 of two adjacent first pixels 30 through via holes of the pixel regions 62, so as to drive the first sub-pixels 31 in the first column and the fourth column at the left side at the same time. Another one connection line 60 is connected to second sub-pixels 32 in the two adjacent first pixels 30 through via holes of the pixel regions 62 so as to drive the second sub-pixels 32 in the second column and the fifth column on the left side at the same time. Still another one connection line 60 is connected to third sub-pixels 33 of two adjacent first pixels 30 through via holes of the pixel regions 62, so as to drive the third sub-pixels 33 of the third column and the sixth column at the left side simultaneously. For the conventional Delta arrangement, the space for compressing one pixel in the border may narrow the border by about 70 μm-90 μm, and this space may accommodate other lines, branching units or devices, etc. thereby to facilitate the narrow border. As shown in FIG. 3, the first electrode 301 may be an anode, and the first electrode 301 may be in a normal anode arrangement. In a pixel region at the edge, there are only the anode and the opening for the pixel to emit light, with no pixel driving circuit below. This may be applied to a display panel with a circular shape or with rounded corners, so that the panel may have a narrow border.

As shown in FIG. 7, the leftmost pixel regions 62 are in a first column, one connection line 60 is connected to a sub-pixel of the first pixel 30 in the pixel region 62 of the first column and a sub-pixel of the first pixel 30 in the pixel region 62 of the fourth column through via holes of the pixel regions 62, so as to simultaneously drive the first sub-pixel of the first pixel 30 in the first column on the left side and the fourth column. Another one connection line 60 is connected to a sub-pixel of the first pixel 30 in the pixel region 62 of the second column and a sub-pixel of the first pixel 30 in the pixel region 62 of the fifth column through via holes of the pixel regions 62, so as to simultaneously drive a second sub-pixels of the first pixel 30 in the second column and the fifth column on the left side. Still another one connection line 60 is connected to a sub-pixel of the first pixel 30 in the pixel region 62 of the third column and a sub-pixel of the first pixel 30 in the pixel region 62 of the sixth column through via holes of the pixel regions 62, so as to simultaneously drive third sub-pixels of the first pixel 30 in the third column and the sixth column on the left side. It is able to compress the space of two pixels in the border, in the pixel region at the left edge, there are only the anode and the opening for the pixel to emit light, with no pixel driving circuit below, which may be applied to a rectangular display panel, allowing the panel to have a narrow border. To avoid excessive length of the connection line 60, there may be one, two or three sub-pixels between two sub-pixels connected by the same connection line 60.

As shown in FIGS. 4 and 5, each connection line 60 is connected to two first pixels 30, and each connection line 60 is connected to two first pixels 30 adjacent to each other through via holes of the pixel regions 62. For example, as shown in FIG. 4, with regard to pixel regions 62 located in a middle row, the leftmost is a first column, one connection line 60 is connected to first sub-pixels 31 of two adjacent first pixels 30 through via holes of the pixel regions 62, e.g., the first sub-pixels 31 in a first column and a fourth column on the left side, a track located at the position of the first sub-pixel 31 in the seventh column may be connected to one first driving circuit 51, the connection line 60 is not electrically connected to the first sub-pixel 31 located in the seventh column, and the first driving circuit 51 is connected to the connection line 60 via the track, thereby driving the first sub-pixels 31 in the first column and the fourth column on the left side at the same time. Another one connection line 60 is connected to the second sub-pixels 32 in two adjacent first pixels 30 through via holes of the pixel regions 62, e.g., the second sub-pixels 32 in the second column and the fifth column on the left side, so as to drive the second sub-pixels 32 in the second left column and the fifth column at the same time via the same first driving circuit 51. Still another one connection line 60 is connected to third sub-pixels 33 of two adjacent first pixels 30 through via holes of the pixel regions 62, e.g., the third sub-pixels 33 in the third column and the sixth column on the left side, so as to drive the third sub-pixels 33 in the third column and the sixth column on the left side simultaneously via the same first driving circuit 51. With the above-mentioned arrangement, it is able to compress and obtain the spatial region of two pixels in the border, so that the border may be narrowed by about 140 μm-180 μm, and this space may accommodate more units and lines, thereby to achieve an ultra-narrow border. As shown in FIG. 5, the first electrode 301 may be an anode, and the first electrode 301 may be in a normal anode arrangement, and in two pixel regions at the edge, there are only the anode and the opening for the pixel to emit light, with no pixel driving circuit below. With regard to the narrowing of the left and right borders, when two pixels are driven by one first driving circuit 51 in the left and right borders, the space in an underlying pad region also benefits. This is mainly because corners of the underlying pad shrink towards the display region, allowing the lines to shrink upwards and towards inside of the display region, which is beneficial to the narrowing of the lower border.

Optionally, the display panel further includes: a detection circuit configured to detect brightness of a pixel, at least part of the detection circuit is located in the first display region 11, for example, part of the detection circuit is located in the first display region 11, or the detection circuit is entirely located in the first display region 11. At least part of the detection circuit may be located in the space saved in the first display region 11 due to the first driving circuit 51, at least part of the detection circuit may overlap the first pixel 30, and at least part of the detection circuit may be located below the first pixel 30. The detection circuit may be placed in the first display region 11, so that the detection circuit is closer to the display region, which is beneficial to save the space occupied by the detection circuit in a corresponding region of the frame body, thereby to provide a narrower border.

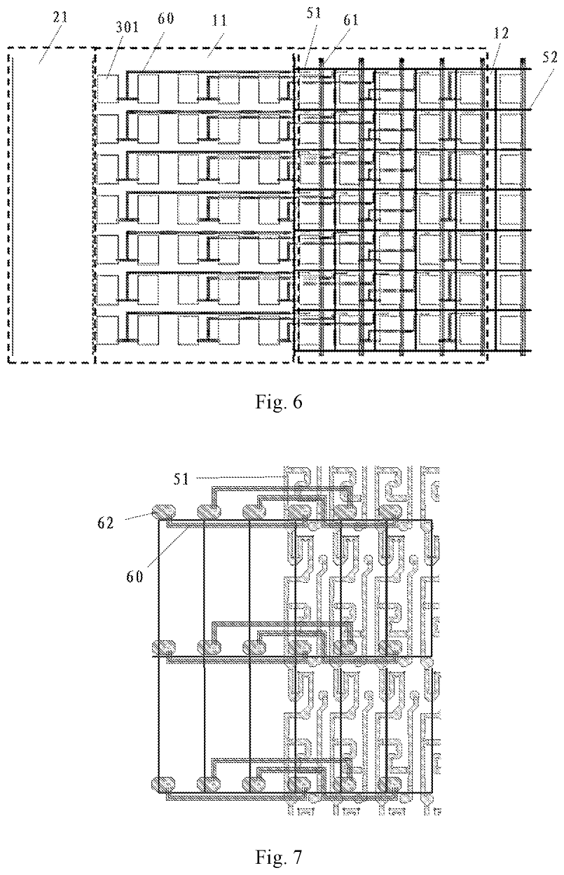

Optionally, as shown in FIG. 6, the display panel further includes: a branching unit 61, the first driving circuit 51 and the first pixel 30 are electrically connected via the branching unit 61, so as to facilitate the electrical connection between the first driving circuit 51 and the first pixel 30, and different branching lines in the branching unit 61 may connect different first pixels 30. The first driving circuit 51 is electrically connected to the first pixels 30 via the branching unit 61, the first pixels 30 are electrically connected to the branching unit 61 via the connection lines 60, each connection line 60 may be connected to two adjacent first pixels 30, and each branching line in the branching unit 61 may be connected to two adjacent first pixels 30, thereby facilitating the arrangement of lines while facilitating the reduction of space occupation.

Optionally, at least part of the branching unit 61 is located in the first display region 11, for example, a part of the branching unit 61 may be located in the first display region 11, the space saved by the first driving circuit 51 in the first display region 11 may be used to accommodate the branching unit 61, and the space occupied by the branching unit 61 in a corresponding region of the frame body may be reduced, thereby to provide a narrower border.

Optionally, the first display region 11 includes a first region 111, a second region 112, a third region 113 and a fourth region 114, the first region 111, the second region 112, the third region 113 and the fourth region 114 are distributed along the periphery of the second display region 12, and the first pixels are arranged in at least one of the first region 111, the second region 112, the third region 113 and the fourth region 114. When closing to the region where the first pixels 30 are distributed, it is advantageous to making the border narrower.

Optionally, a distribution density of the first pixels 30 in the first display region 11 is less than a distribution density of the second pixels 40 in the second display region 12. Since the distribution density of the first pixels 30 in the first display region 11 is less than the distribution density of the second pixels 40 in the second display region 12, the quantity of the first driving circuits required for driving the first pixels 30 in the first display region 11 is reduced, the space occupied by the first driving circuits 51 is reduced, and the saved space may be used to accommodate other lines or devices, which is beneficial to increasing the area of the display region and narrowing the border of the display panel.

The display device according to the embodiments of the present disclosure, including the display panel described in the above-described embodiments, which may make the frame body narrower and facilitate miniaturization.

The display device further includes: a frame body covering the non-display region 20. The frame body may be arranged in a border region 21 of the non-display region 20, and the border region 21 may surround the periphery of the first display region 11. Since the space saved by the first driving circuit 51 in the first display region 11 may be used to accommodate other lines or devices, it is able to reduce the space occupation for the non-display region 20 and make the frame body narrower.

The embodiments of the present disclosure are described above with reference to the accompanying drawings. However, the present disclosure is not limited to the foregoing specific implementations. The foregoing specific implementations are merely illustrative rather than limitative. In light of the teachings of the present disclosure, a person of ordinary skill in the art may further make various forms without departing from the spirit of the present disclosure and the scope of the claims, and these forms all fall within the scope of the present disclosure.

1. A display panel, comprising
a display region and a non-display region, wherein the non-display region surrounds the display region, the display region comprises a first display region and a second display region, the first display region surrounds the periphery of the second display region, a plurality of first pixels is arranged in the first display region, a plurality of second pixels is arranged in the second display region, the display region comprises a first driving circuit configured to drive the first pixels and a second driving circuit configured to drive the second pixels; and
one first driving circuit is configured to simultaneously drive at least two first pixels.

2. The display panel according to claim 1, wherein one first driving circuit is configured to simultaneously drive two first pixels in two adjacent columns respectively.

3. The display panel according to claim 2, wherein two first pixels respectively in two columns driven simultaneously by a same first driving circuit are in a same row.

4. The display panel according to claim 1, wherein at least part of the first driving circuit is arranged in the second display region.

5. The display panel according to claim 1, further comprising:
connection lines, wherein each of the connection lines is connected to electrodes of at least two first pixels, and each first driving circuit is electrically connected to a corresponding one of the connection lines.

6. The display panel according to claim 5, wherein each of the connection lines is connected to two adjacent first pixels.

7. The display panel according to claim 1, wherein each of the first pixels comprises a first sub-pixel, and one first driving circuit is configured to simultaneously drive first sub-pixels of at least two first pixels.

8. The display panel according to claim 7, wherein each of the first pixels comprises a second sub-pixel, and one first driving circuit is configured to simultaneously drive second sub-pixels of at least two first pixels, wherein the first sub-pixel and the second sub-pixel emit light in different colors.

9. The display panel according to claim 1, wherein the first pixel comprises:
a first electrode, a light-emitting unit and a second electrode laminated one on another, and one first driving circuit is configured to connect electrodes in at least two first pixels.

10. The display panel according to claim 1, further comprising:
a detection circuit configured to detect brightness of a pixel, at least part of the detection circuit being located in the first display region.

11. The display panel according to claim 1, further comprising:
a branching unit, wherein the first driving circuit is electrically connected to the first pixels via the branching unit.

12. The display panel according to claim 11, wherein at least part of the branching unit is located in the first display region.

13. The display panel according to claim 1, wherein the first display region comprises a first region, a second region, a third region and a fourth region, the first region, the second region, the third region and the fourth region are distributed along the periphery of the second display region, and the first pixels are arranged in at least one of the first region, the second region, the third region and the fourth region.

14. The display panel according to claim 1, wherein a distribution density of the first pixels in the first display region is less than a distribution density of the second pixels in the second display region.

15. A display device comprising the display panel according to claim 1; wherein the display device further comprises: a frame body covering the non-display region.

16. The display device according to claim 15, wherein one first driving circuit is configured to simultaneously drive two first pixels in two adjacent columns respectively.

17. The display device according to claim 15, wherein at least part of the first driving circuit is arranged in the second display region.

18. The display device according to claim 15, wherein the display panel further comprises:
connection lines, wherein each of the connection lines is connected to electrodes of at least two first pixels, and each first driving circuit is electrically connected to a corresponding one of the connection lines.

19. The display device according to claim 15, wherein the display panel further comprises:
a branching unit, wherein the first driving circuit is electrically connected to the first pixels via the branching unit.

20. The display device according to claim 15, wherein a distribution density of the first pixels in the first display region is less than a distribution density of the second pixels in the second display region.
